(19) United States
(12) Patent Application Publication
(10) Pub. No.: US 2013/0128249 A1
(43) Pub. Date: May 23, 2013

(54) Fiber Delivery for Metrology Systems Used in Lithography Tools

(71) Applicant: Zygo Corporation, Middlefield, CT (US)

(72) Inventor: Kurt Redlitz, Middlefield, CT (US)

(73) Assignee: Zygo Corporation, Middlefield, CT (US)

(21) Appl. No.: 13/672,556

(22) Filed: Nov. 8, 2012

Related U.S. Application Data
(60) Provisional application No. 61/557,601, filed on Nov. 9, 2011.

(51) Int. Cl. G03F 7/20

(52) U.S. Cl. CPC G03F 7/70958
USPC 355/67

(57) ABSTRACT

Metrology system, apparatus and method used to implement measurements inside a lithography tool are described, such that the disclosed measurements can be performed without contributing outgassed effluent within the lithography tool. Disclosed is a system including: an objective for projecting an image of an object positioned at an object plane to an image plane; a stage to execute motions relative to the objective while supporting the wafer at the image plane; an optical sensor for producing an optical monitoring signal associated with the motions of the stage; and a glass optical fiber having a metal outer coating, the metal-coated glass optical fiber being arranged to provide light to, or collect light from, the optical sensor.

### CROSS-REFERENCE TO RELATED APPLICATIONS

This application claims benefit of the Provisional Application No. 61/557,601, entitled “Fiber delivery for metrology systems used in lithography tools,” filed on Nov. 9, 2011. The entire content of this priority application is hereby incorporated by reference.

### BACKGROUND

The disclosure relates to lithography tools equipped with metrology systems that use fiber optic cables to distribute measurement signals associated with the metrology systems.

A lithography tool, also referred to as an exposure system, typically includes an illumination system and a wafer positioning system. The illumination system includes a radiation source for providing radiation such as ultraviolet, visible, x-ray, electron, or ion radiation, and a reticle or mask for imparting the pattern to the radiation, thereby generating the spatially patterned radiation. In addition, for the case of reduction lithography, the illumination system can include a lens assembly (e.g., a projection objective) for imaging the spatially patterned radiation onto the wafer. The imaged radiation exposes resist coated onto the wafer. The illumination system also includes a mask stage for supporting the mask and a positioning system for adjusting the position of the mask stage relative to the radiation directed through the mask. The wafer positioning system includes a wafer stage for supporting the wafer and a positioning system for adjusting the position of the wafer stage relative to the imaged radiation. Fabrication of integrated circuits can include multiple exposing steps. For a general reference on lithography, see, for example, J. R. Sheats and B. W. Smith, in Microlithography: Science and Technology (Marcel Dekker, Inc., New York, 1998), the contents of which is incorporated herein by reference.

Metrology systems can be used to precisely measure the positions of each of the wafer stage and mask stage relative to other components of the exposure system, such as the lens assembly, radiation source, or support structure. In such cases, a sensor of the metrology system can be attached to a stationary structure and a scale of the metrology system can be attached to a movable element such as one of the mask and wafer stages. Alternatively, the situation can be reversed, with the sensor attached to a movable object and the scale attached to a stationary object. Measurement signals associated with the metrology system can be delivered to and from the sensor of the metrology system using optical fiber cables.

### SUMMARY

In general, lithography exposure systems are subject to contamination from outgassed effluent from materials used to construct these systems. This contamination decreases the productivity of the lithography tool as it requires more frequent cleaning to maintain its specified performance. In some cases, contamination can shorten the effective life of a lithography tool because certain sub-systems cannot be cleaned without being returned to the original equipment manufacturer for completely disassembly.

Photodeposition is defined is a synthesis technique where monomers are irradiated with UV light, causing cross-linking and deposition of the resulting polymers on a substrate. There are many potential sources for monomers in exposure systems. Typical sources include the outgassed effluent from adhesives, polymer-based components, cleaning solutions, solvents, and coolants. As this effluent passes through an exposure sub-system inside an exposure system, it is cross-linked and deposited by light used in the system to lithographically reproduce an image onto a substrate. In the case of semiconductor lithography systems, typical exposure wavelengths are 248 nm and 193 nm. In this fashion, these short wavelengths combined with total optical dosage use in the exposure system can cause parasitic photodeposition of the outgassed effluent inside the exposure system. To reduce parasitic photodeposition and therefore increase the value of the exposure systems, materials used in lithography system components are tightly controlled.

This disclosure relates to metrology system, apparatus and method used to implement measurements inside a lithography tool, such that the disclosed measurements can be performed without contributing outgassed effluent within the lithography tool. For example, optical signals associated with the disclosed measurements can be delivered to the metrology system or between components of the metrology system using optical cables including glass fibers that have metal outer coatings, such as Metal Coated Silica (“MCS”) optical fibers.

Various aspects of the invention are summarized as follows.

In general, in a first aspect, the invention features a system including: an objective for projecting an image of an object positioned at an object plane to an image plane; a stage to execute motions relative to the objective while supporting the wafer at the image plane; an optical sensor for producing an optical monitoring signal associated with the motions of the stage; and a glass optical fiber having a metal outer coating, the metal-coated glass optical fiber being arranged to provide light to, or collect light from, the optical sensor.

Embodiments can include one or more of the following features.

For example, the system can further include an exposure chamber enclosing at least (i) the stage and (ii) at least a portion of the metal-coated glass optical fiber comprising the fiber end near the optical sensor, the exposure chamber being arranged and configured to maintain a predefined concentration level of outgassed effluent during the exposure. The glass optical fiber having the metal outer coating outgasses substantially no effluent inside the exposure chamber.

The metal-coated glass optical fiber can collect light from the optical sensor at one end, the collected light carrying the optical monitoring signal. The system can further include signal processing electronics coupled to another end of the metal-coated glass optical fiber such that the optical monitoring signal is received by the signal processing electronics, the signal processing electronics being configured to monitor, based on the optical monitoring signal, a relative position of the stage.

The stage position, which is monitored by the signal processing electronics based on the optical monitoring signal, can be along a first degree of freedom of the stage. Furthermore, the system can include one or more other metal-coated glass optical fibers to monitor corresponding one or more other stage positions along respective one or more other degrees of freedom associated with the stage. The one or more other metal-coated glass optical fibers outgas substantially no effluent inside the exposure chamber.

The system can further include an optical source for the optical sensor, and the metal-coated glass optical fiber can provide light to the optical sensor from the optical source. For example, the optical source can be a heterodyne light source that provides light at two different frequencies with orthogonal polarizations. The metal-coated glass optical fiber can be a polarization-preserving optical fiber to preserve such orthogonal polarizations. Alternatively, the system can include a second metal-coated glass optical fiber for providing light to the optical sensor from the optical source.

The system can also include multiple metal-coated glass optical fibers to provide light to, and collect light from, the optical sensor.

The optical sensor can be optical encoder, such as an interferometric optical encoder. For example, the optical encoder can operate at a non-Littrow, diffractive angle.

The optical monitoring signal can be collected at the fiber end by imaging the optical monitoring signal on the surface of the fiber end. Furthermore, in certain embodiments, a polarizer can be placed between the stage and the end of the metal-coated glass optical fiber to collect the optical monitoring signal, the polarizer arranged to mix two orthogonally polarized optical signals into an interference signal representing the optical monitoring signal. In other embodiments, a polarizer can be placed between the other end of the metal-coated glass optical fiber and the signal processing electronics, the polarizer arranged to mix two orthogonally polarized optical signals representing the optical monitoring signal into an interference signal input to the signal processing electronics.

The metal outer coating of the glass optical fiber can include any of Al, Cu, Sn, Au, In, Pb, Zn, and Ni, and preferably, at least one of Al, Cu, and Sn. The metal outer coating of the glass optical fiber can have a thickness in the range of 15 to 50 microns. The glass optical fiber can include a core of silica and a cladding of doped silica.

Particular implementations of the subject matter described in this specification can be configured so as to realize one or more of the following potential advantages. MCS optical fibers offer the benefits of standard silica-silica fibers. In addition, the metal outer coating protects the glass fiber without outgassing effluent as other fiber outer coatings. Moreover, the metal coating provides additional benefits, such as increased mechanical strength and greater fatigue resistance when compared to non-hermetic polymer-clad fibers (PCS).

Various references are incorporated herein by reference. In the event of conflict, the present specification controls.

The details of one or more embodiments are set forth in the accompanying drawings and the description below. Other features and advantages will be apparent from the description and drawings, and from the claims.

### DESCRIPTION OF DRAWINGS

FIG. 1 shows an example of a lithography tool that includes sensing technology for stage control.

FIG. 2 shows an example of a photolithographic system equipped with a metrology system that uses metal coated glass optical fibers to distribute optical signals to and from the metrology system placed inside an exposure chamber of the photolithographic system.

FIG. 3A shows an example of a metrology system including an encoder system.

FIG. 3B shows a portion of an example of an encoder system.

FIG. 4 shows a process used to maintain below a predetermined level a concentration of outgassed effluent inside an exposure chamber of a lithography system by using optical sensing technology including an optical signal transport system that eliminates outgassed effluent.

Like reference symbols in the various drawings indicate like elements.

### DETAILED DESCRIPTION

Lithography tools are especially useful in lithography applications used in fabricating large scale integrated circuits such as computer chips and the like. Lithography is the key technology driver for the semiconductor manufacturing industry. Overlay improvement is one of the five most difficult challenges down to and below 100 nm line widths (design rules), see, for example, the 2010 International Technology Roadmap for Semiconductors, which target flash memory half pitches of 20 nm by 2014. The function of a lithography tool is to direct spatially patterned radiation onto a photoresist-coated wafer. The process involves determining which location of the wafer is to receive the radiation (alignment) and applying the radiation to the photoresist at that location (exposure).

During exposure, a radiation source illuminates a patterned reticle, which scatters the radiation to produce the spatially patterned radiation. The reticle is also referred to as a mask, and these terms are used interchangeably below. In the case of reduction lithography, a reduction lens collects the scattered radiation and forms a reduced image of the reticle pattern. Alternatively, in the case of proximity printing, the scattered radiation propagates a small distance (typically on the order of microns) before contacting the wafer to produce a 1:1 image of the reticle pattern. The radiation initiates photo-chemical processes in the resist that convert the radiation pattern into a latent image within the resist.

To properly position the wafer, the wafer includes alignment marks on the wafer that can be measured by dedicated sensors. The measured positions of the alignment marks define the location of the wafer within the tool. This information, along with a specification of the desired patterning of the wafer surface, guides the alignment of the wafer relative to the spatially patterned radiation. Based on such information, a translatable stage supporting the photoresist-coated wafer moves the wafer such that the radiation will expose the correct location of the wafer. In certain lithography tools, e.g., lithography scanners, the mask is also positioned on a translatable stage that is moved in concert with the wafer during exposure.

Metrology systems are important components of the positioning mechanisms that control the position of the wafer and reticle, and register the reticle image on the wafer. The accuracy of distances measured by the metrology systems can be increased and/or maintained over longer periods without offline maintenance, resulting in higher throughput due to increased yields and less tool downtime. The metrology systems can be used to measure the position of any one component of the exposure system relative to any other component of the exposure system, in which a sensor of the metrology system is attached to, or supported by, one of the components and a scale of the metrology system is attached to, or is supported by the other of the components.

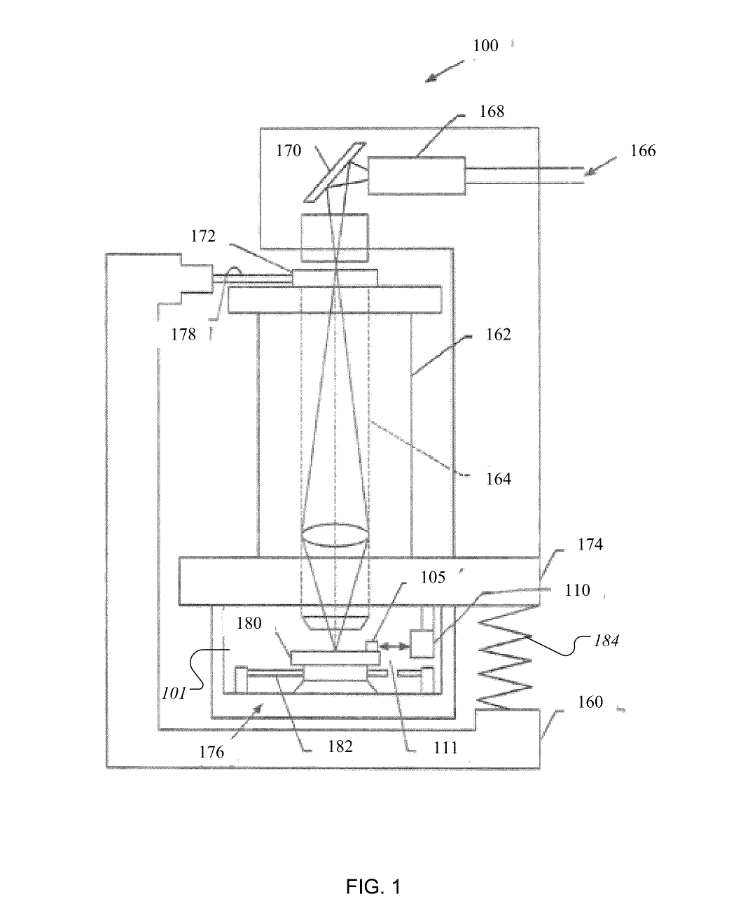

FIG. 1 shows an example of a lithography tool 100 that uses a metrology system including, at least in part, a sensor 110 and a sensor scale 105. The lithography tool 100 can be referred to as a scanner or an exposure system. In some implementations, the metrology system can be an encoder system used to precisely measure the position of a wafer (not shown) within the exposure system 100. Here, a stage 180 is used to position and support the wafer relative to a lens housing 162. The sensor scale 105 can be an alignment mark configured and arranged to reflect or diffract a measurement beam 111 from the stage 180 to the sensor 110.

Scanner 100 includes a frame 160, which carries other support structures and various components carried on those structures. An exposure base 174 has mounted on top of it the lens housing 162 atop of which is mounted a reticle or mask stage 172, which is used to support a reticle or mask. A positioning system for positioning the mask relative to the exposure station is indicated schematically by element 178. Positioning system 178 can include, e.g., piezoelectric transducer elements and corresponding control electronics. Although, it is not included in this described embodiment, one or more additional metrology systems can be used to precisely measure the position of the mask stage 172 as well as other moveable elements whose position must be accurately monitored in processes for fabricating lithographic structures.

Suspended below exposure base 174 is a support base 176 that carries the wafer stage 180. The volume enclosed by the exposure base 174 and the support base 176 can be referred to as an exposure chamber 101. In some implementations, the lithography tool 100 is configured and arranged to maintain a concentration of outgassed effluent below a predetermined level inside the exposure chamber 101, in order to minimize an amount of the outgassed effluent that can react with the exposure radiation (from a radiation beam 166 or from scattered radiation within the exposure chamber 101) to cause parasitic photodeposition of the outgassed effluent. At least for this reason, materials used to fabricate components disposed inside the exposure chamber 101 are tightly controlled.

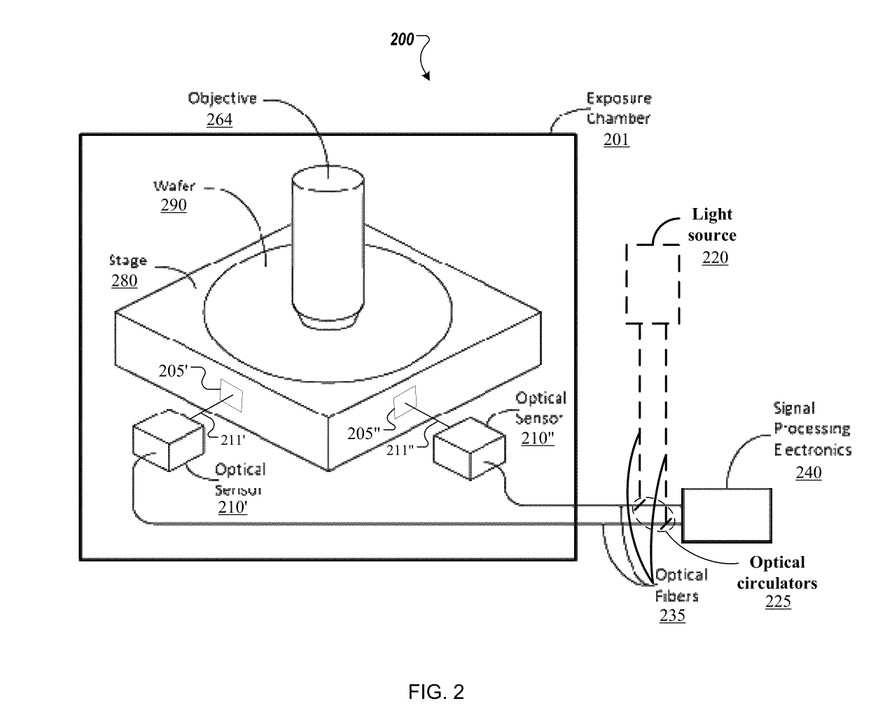

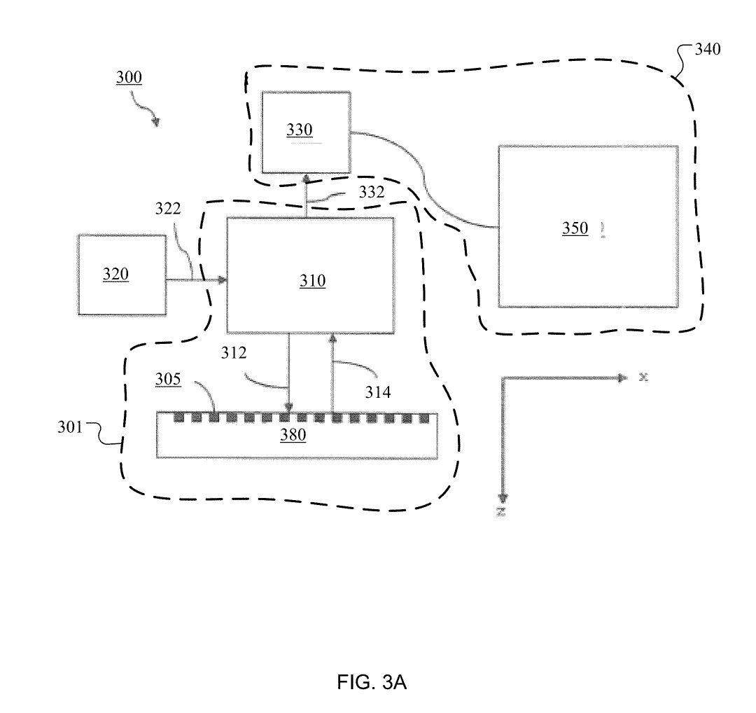

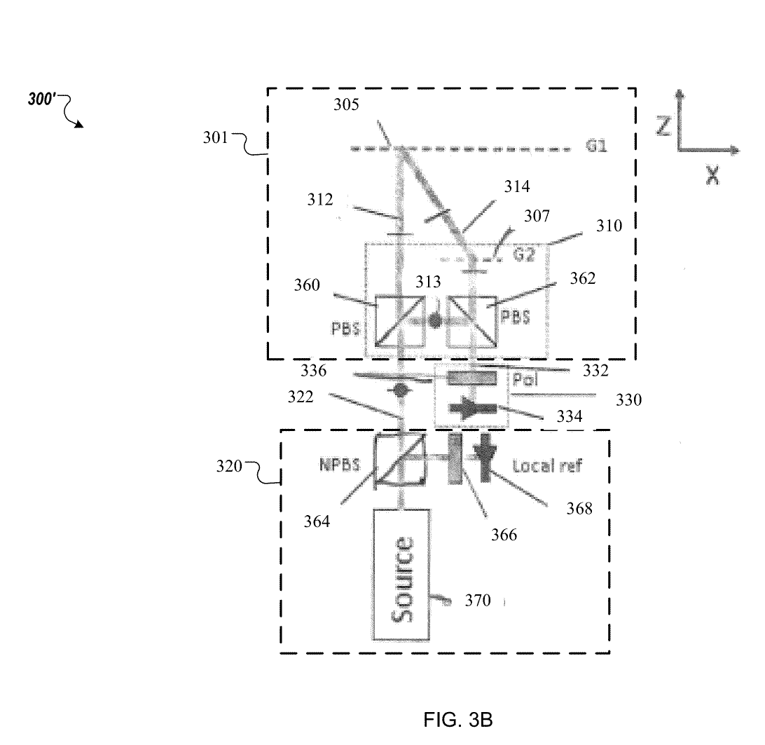

Inside the exposure chamber 101, the sensor scale 105 can be attached to the stage 180 for reflecting or diffracting a measurement beam 111 directed to the stage 180 by the sensor 110. A positioning system for positioning the stage 180 relative to the sensor 110 is indicated schematically by the element 182. Positioning system 182 can include, e.g., piezoelectric transducer elements and corresponding control electronics. The sensor scale 105 reflects or diffracts the measurement beam 111 back to the sensor 110, which is mounted on exposure base 174. Examples of metrology systems that can be disposed inside the exposure chamber 101 are described below in connection with FIGS. 2 and 3A-3B.

During operation, the radiation beam 166, e.g., an ultraviolet (UV) beam from a UV laser (not shown), passes through a beam shaping optics assembly 168 and travels downward after reflecting from mirror 170. Thereafter, the radiation beam 166 passes through a mask (not shown) carried by mask stage 172. The mask (not shown) is imaged onto a wafer (not shown) on wafer stage 180 via a lens assembly 164 carried in the lens housing 162. The exposure chamber 101 and the various components inside it are isolated from environmental vibrations by a damping system depicted by spring 184.

In some embodiments, one or more metrology systems can be used to measure displacement along multiple axes and angles associated for example with, but not limited to, the wafer stage 180 and reticle (or mask) stage 172. Also, rather than a UV laser beam, other beams can be used to expose the wafer including, e.g., x-ray beams, electron beams, ion beams, and visible optical beams. Finally, the metrology system that includes the sensor 110 and the sensor scale 105 can be used in a similar fashion with lithography systems involving steppers, in addition to, or rather than, scanners.

FIG. 2 shows a portion of an example of a lithography system 200 that includes an exposure chamber 201. The example lithography system 200 can be implemented as part of the exposure system 100 described above in connection with FIG. 1. In this case, the exposure chamber 201 encloses a semiconductor wafer 290 on a stage 280 that executes precision motions during exposure to a photolithographic pattern projected by an objective 264. Optical sensors 210′ and 210″ in conjunction with signal processing electronics 240 monitor the stage position, providing feedback to the stage motion control (not shown).

The stage position is monitored by the optical sensor 210′ along a first degree of freedom of the stage, and by the optical sensor 210″ along a second degree of freedom of the stage. The optical sensors 210 and 210″ transmit monitoring information via optical signals to the signal processing electronics 240 through glass optical fibers 235 that have metal coatings. The signal processing electronics 240 can include photo-detectors configured to convert the optical signals carrying the monitoring information to electrical signals carrying the monitoring information.

For example, the optical sensor 210′ probes a sensor scale 205′ attached to the stage 280 with a monitoring beam 211′ to generate a monitoring signal. One of the optical fibers 235 can be arranged to collect, at a fiber end that is inside the exposure chamber 201, the monitoring signal output by the optical sensor 210′. Further, the one of the optical fibers 235 can be coupled, at another end that is outside the exposure chamber 201, with the signal processing electronics 240 to deliver the transmitted monitoring signal to the latter. As another example, the optical sensor 210″ probes another sensor scale 205″ attached to the stage 280 with another monitoring beam 211″ to generate another monitoring signal. Another one of the optical fibers 235 can be arranged to collect, at a fiber end that is inside the exposure chamber 201, the other monitoring signal output by the optical sensor 210″. Further, the other one of the optical fibers 235 can be coupled, at another end that is outside the exposure chamber 201, with the signal processing electronics 240 to deliver the transmitted other monitoring signal to the latter.

Additionally, a concentration of unwanted monomers in the exposure chamber 201, e.g., effluent that is outgassed from adhesives and polymer-based components, is maintained below a predetermined level to prevent the unwanted monomers in the exposure chamber 201 of the lithography system 200 from cross-linking by light used in the system 200 to lithographically reproduce an image onto the wafer 290. The optical fibers 235 can have silica cores, doped silica cladding and can have a metal outer coating. In this manner, the metal outer coating can protect the glass optical fibers 235. Moreover, the metal outer coatings of the glass optical fibers 235 do not outgas effluent, as fiber outer coatings fabricated from polymers would. In some implementations, the metal outer coating of the glass optical fibers includes one of Al, Cu or Sn (Tin). In addition, the metal outer coating of the glass optical fibers can include one of Au, In, Pb, Zn or Ni. Moreover, the metal outer coating of the glass optical fibers can have a thickness in the range of 15 to 50 microns.

Optionally, input beams provided by a light source 220 placed outside the exposure chamber 201 can be delivered to the respective optical sensors 210′ and 210″ via the metal coated glass optical fibers 235. In some implementations, an input beam can be provided, by the light source 220 to the optical sensor 210′, via a metal coated glass optical fiber that is different from another metal coated glass optical fiber used to transmit the optical monitoring signal from the optical sensor 210′ to the signal processing electronics 240. For example, in certain embodiments, the optical fibers for the input beams are single mode fibers, whereas the return or “pick-up” fibers to transmit the optical monitoring signal are multimode fibers. Furthermore, in certain embodiments, the input optical fibers are polarization preserving fibers.

In other implementations, the input beam can be provided, by the light source 220 to the optical sensor 210′, via the same metal coated glass optical fiber that is used to transmit the optical monitoring signal from the optical sensor 210′ to the signal processing electronics 240. The latter implementations represents reciprocal signal transmissions through optical fibers and can be realized, for example, by using optical circulators 225 and a multiplexer (not shown) to time-multiplex transmissions of the input beam from the light source 220 outside the exposure chamber 201 to the optical sensor 210′ inside the exposure chamber 201 with transmissions of the optical monitoring signal from the optical sensor 210′ inside the exposure chamber 201 to the signal processing electronics 240 outside the exposure chamber 201.

The optical sensors 210′ and 210″ can be part of encoders configured and arranged to monitor displacements of the stage 280 in orthogonal directions. FIG. 3A shows an example of an encoder system 300 that can be used as either of the optical sensors 210′ and 210″ described above in connection with FIG. 2. The encoder system 300 includes a light source module 320 (e.g., including a laser), an optical assembly 310, an encoder scale 305, a detector module 330 (e.g., including a polarizer and a detector), and an electronic processor 350. The detector module 330 and the electronic processor 350 form signal processing electronics 340 in analogy to the signal processing electronics 240 described above in connection with FIG. 2. In some implementations, the sensor scale 305 can be attached to a measurement object 380. The measurement object 380 can be a wafer or a wafer stage, for instance. Generally, light source module 320 includes a light source and can also include other components such as beam shaping optics (e.g., light collimating optics), light guiding components (e.g., fiber optic waveguides) and/or polarization management optics (e.g., polarizers and/or wave plates). The optical assembly 310 is also referred to as the “encoder head.” A Cartesian coordinate system is shown for reference. In the case of the decoder 300 illustrated in FIG. 3A, the encoder head 310 and the measurement object 380 (where the latter includes the encoder scale 305) are inside an exposure chamber 301 of a lithography tool. Moreover, the light source 320 and the signal processing electronics 340 (the latter including the detector module 330 and the electronic processor 350) are placed outside of the exposure chamber 301.

Measurement object 380 can be positioned some nominal distance from optical assembly 310 along the Z-axis. In many applications, such as where the encoder system 300 is used to monitor the position of a wafer stage or reticle stage in a lithography tool, measurement object 380 is moved relative to the optical assembly in the X- and/or Y-directions while remaining nominally a constant distance from the optical assembly relative to the Z-axis. This constant distance can be relatively small (e.g., a few centimeters or less). However, in such applications, the location of measurement object 380 typically will vary a small amount from the nominally constant distance and the relative orientation of the measurement object 380 within the Cartesian coordinate system can vary by small amounts too. During operation, encoder system 300 monitors one or more of these degrees of freedom of measurement object 380 with respect to optical assembly 310, including a position of measurement object 380 with respect to the x-axis, and further including, in certain embodiments, a position of the measurement object 380 with respect to the y-axis and/or z-axis and/or with respect to pitch and yaw angular orientations.

To monitor the position of measurement object 380, source module 320 placed outside the exposure chamber 301 directs an input beam 322 to the optical assembly 310 disposed inside the exposure chamber 301. The input beam 322 can be delivered from the source module 320 to the optical assembly 310 via a metal coated optical fiber (e.g., one of the metal coated optical fibers 235 described above in connection with FIG. 2.) For example, an end of the metal coated optical fiber that is outside of the exposure chamber 301 can be connected to the output of the source module 320, and another end of the metal coated optical fiber that is inside of the exposure chamber 301 can be connected to the input of the optical assembly 310. By using a metal coated optical fiber to deliver the input beam 322 to the optical assembly 310, the encoder system 300 contributes no outgassing effluent inside the exposure chamber 301.

Optical assembly 310 derives a measurement beam 312 from input beam 322 and directs measurement beam 312 to measurement object 380. Optical assembly 310 also derives a reference beam (not shown) from input beam 322 and directs the reference beam along a path different from the measurement beam 312. For example, optical assembly 310 can include a beam splitter that splits input beam 322 into measurement beam 312 and the reference beam. The measurement and reference beams can have orthogonal polarizations (e.g., orthogonal linear polarizations).

The encoder scale 305 can be attached to or can be part of the measurement object 308. In some implementations, the encoder scale 305 can be an alignment marker that reflects the measurement beam 312 from the encoder head 310, as a reflected beam 314, back to the encoder head 310. In other implementations, the encoder scale 305 can be a measuring graduation that diffracts the measurement beam 312 from the encoder head 310 into one or more diffracted orders 314. In general, encoder scales can include a variety of different diffractive structures such as gratings or holographic diffractive structures. Examples or gratings include sinusoidal, rectangular, or saw-tooth gratings. Gratings can be characterized by a periodic structure having a constant pitch, but also by more complex periodic structures (e.g., chirped gratings). In general, the encoder scale 305 can diffract the measurement beam 312 into more than one plane. For example, the encoder scale 305 can be a two-dimensional grating that diffracts the measurement beam 312 into diffracted orders in the X-Z and Y-Z planes. The encoder scale 305 extends in the X-Y plane over distances that correspond to the range of the motion of measurement object 380.

In the present embodiment, encoder scale 305 is a grating having grating lines that extend orthogonal to the plane of the page, parallel to the Y-axis of the Cartesian coordinate system shown in FIG. 3A. The grating lines are periodic along the X-axis. Encoder scale 305 has a grating plane corresponding to the X-Y plane and the encoder scale 305 diffracts measurement beam 312 into one or more diffracted orders 314 in the Y-Z plane. At least one of these diffracted orders of the measurement beam (labeled beam 114), returns to optical assembly 310, where it is combined with the reference beam to form an output beam 332. For example, the once-diffracted measurement beam 314 can be the first-order diffracted beam.

Output beam 332 includes phase information related to the optical path length difference between the measurement beam 312 and the reference beam. The optical assembly 310 placed inside the exposure chamber 301 directs the output beam 332 to the signal processing electronics 340 placed outside the exposure chamber 301. The output beam 332 can be delivered from the optical assembly 310 to the signal processing electronics 350 via a metal coated optical fiber (e.g., one of the metal coated optical fibers 235 described above in connection with FIG. 2.) For example, an end of the metal coated optical fiber that is inside of the exposure chamber 301 can be connected to the output of the optical assembly 310, and another end of the metal coated optical fiber that is outside of the exposure chamber 301 can be connected to the input of the detector module 330 of the signal processing electronics 340. By using metal coated optical fibers to deliver the output beam 332 from the optical assembly 310, the encoder system 300 contributes no outgassing effluent inside the exposure chamber 301.

The detector module 330 of the signal processing electronics 340 detects the output beam and sends a signal to electronic processor 350 in response to the detected output beam. Electronic processor 350 receives and analyzes the signal and determines information about one or more degrees of freedom of measurement object 380 relative to optical assembly 310.

In certain embodiments, the measurement and reference beams have a small difference in frequency (e.g., a difference in the kHz to MHz range) to produce an interferometry signal of interest at a frequency generally corresponding to this frequency difference. This frequency is hereinafter referred to interchangeably as the “heterodyne” frequency or the “reference” frequency. Information about the changes in the relative position of the measurement object 380 generally corresponds to a phase of the interferometry signal at this heterodyne frequency. Signal processing techniques can be used to extract this phase. In general, the moveable measurement object 380 causes this phase term to be time-varying. In this regard, the first order time derivative of the measurement object movement causes the frequency of the interferometry signal to shift from the heterodyne frequency by an amount referred to herein as the “Doppler” shift.

The different frequencies of the measurement and reference beams can be produced, for example, by laser Zeeman splitting, by acousto-optical modulation, using two different laser modes, or internal to the laser using birefringent elements, among other techniques. The orthogonal polarizations allow a polarizing beam-splitter to direct the measurement and reference beams along different paths, and combine them to form the output beam 332 that subsequently passes through a polarizer, which mixes the orthogonally polarized components so they can interfere. In the absence of target motion the interference signal oscillates at the heterodyne frequency, which is just the difference in the optical frequencies of the two components. In the presence of motion the heterodyne frequency incurs a change related to the velocity of the target through well-known Doppler relations. Accordingly, monitoring changes in the heterodyne frequency allows one to monitor motion of the target 380 relative to the optical assembly 310.

In the embodiments described below, the input beam 322 generally, refers to the beam emitted by the light source module 320. For heterodyne detection, the input beam 322 includes components having slightly different frequencies, as discussed above.

In general, the measurement beam 312 is incident on measurement object 380 at an incident angle such that the once-diffracted measurement beam 314 does not satisfy the Littrow condition. The Littrow condition refers to an orientation of a diffractive structure 305, such as a grating, with respect to an incident beam 312 where the diffractive structure 305 directs the diffracted beam 314 back towards the source 310. In other words, in encoder system 300, the once-diffracted measurement beam 314 is non-co-linear with the measurement beam 312 prior to diffracting at the encoder scale 305.

While encoder scale 305 is depicted in FIG. 3A as a structure that is periodic in one direction, more generally, the measurement object 380 can include a variety of different diffractive structures that appropriately diffract the measurement beam 312. In some embodiments, the measurement object 380 can include a diffractive structure (e.g., an encoder scale 305) that is periodic in two directions (e.g., along the x- and y-axis), diffracting the measurement beam 312 into beams in two orthogonal planes. In general, the diffractive structure of the encoder scale 305 and source module 320 are selected so that the encoder system 300 provides one or more diffracted measurement beams 314 having sufficient intensity to establish one or more detectable interference signals when combined with corresponding reference beams, within the geometrical constraints for the system. In some embodiments, the source module 320 provides an input beam 322 having a wavelength in a range from 400 nm to 1,500 nm. For example, the input beam 322 can have a wavelength of about 633 nm or about 980 nm. Note that, in general, the frequency splitting of the heterodyne source 320 results in only a very small difference between the wavelength of the two components of the input beam, so even though the input beam 322 is not strictly monochromatic it remains practical to characterize the input beam by a single wavelength. In some embodiments, the source module 320 can include a gas laser (e.g., a HeNe laser), a laser diode or other solid-state laser source, a light-emitting diode, or a thermal source such as a halogen light with or without a filter to modify the spectral bandwidth.

In general, the diffractive structure 305 (e.g., grating pitch) can vary depending on the wavelength of the input beam 322 and the arrangement of optical assembly 310 and diffracted orders 314 used for the measurement. In some embodiments, the diffractive structure 305 is a grating having a pitch in a range from about 1λ to about 20λ, where λ is a wavelength of the source. The grating 305 can have a pitch in a range from about 1 μm to about 10 μm.

FIG. 3B shows an example of an encoder system 300′ arranged so that the measurement beam 312 makes a single pass to the encoder scale 305 (grating G1) and a single diffracted order of the measurement beam 314 is used for the measurement. In this example, an optical assembly 310 and a scale 305 of the encoder system 300′ are inside the exposure chamber 301. Moreover, a source module 320 and a detector module 330 are placed outside of the exposure chamber 301.

An optical assembly 310 of the encoder system 300′ includes a first polarizing beam splitter (PBS) 360, a second PBS 362, and a grating G2 307. The input beam 322 can be delivered to the optical assembly 310 inside the exposure chamber 301 via a metal coated optical fiber (e.g., one of the metal coated optical fibers 235 described above in connection with FIG. 2.) For example, an end of the metal coated optical fiber that is outside of the exposure chamber 301 can be connected to a non-polarizing beam splitter 364 at the output of the source module 320. Another end of the metal coated optical fiber that is inside of the exposure chamber 301 can be connected to the first PBS 360 at the input of the optical assembly 310. By using the metal coated optical fiber to deliver the input beam 322 to the first PBS 360 of the encoder head 310, the means for delivering the input beam 322 contribute no outgassing effluent inside the exposure chamber 301.

Detector module 330 includes a polarizer 336 and a detector 334. PBS 360 splits input beam 322 into measurement beam 312 and a reference beam 313. As shown, measurement beam 312 is polarized in the plane of the figure (p-polarization), while secondary beam 313 is polarized orthogonal to the plane of the figure (s-polarization). Measurement beam 312 is diffracted by encoder scale 305, providing a once-diffracted measurement beam 314 that corresponds to a non-zeroth diffracted order (e.g., first order or second order) of measurement beam 312. Grating G2 307, which can have a diffractive structure similar to the grating G1 of the encoder scale 305 (e.g., the same pitch) diffracts once-diffracted measurement beam 314 so that the now twice-diffracted measurement beam is incident on PBS 362 along a path parallel to the path of undiffracted measurement beam 312. PBS 362 combines twice-diffracted measurement beam 314 with reference beam 313 to form output beam 332.

The output beam 332 can be delivered from the encoder head 310 inside the exposure chamber 301 to the detector module 330 via a metal coated optical fiber (e.g., one of the metal coated optical fibers 235 described above in connection with FIG. 2.) For example, an end of the metal coated optical fiber that is inside of the exposure chamber 301 can be connected to the PBS 362 at the output of the optical assembly 310, and another end of the metal coated optical fiber that is outside of the exposure chamber 301 can be connected to the polarizer 336 at the input of the detector module 330. Moreover, the output beam 332 can be coupled to the fiber end located inside the exposure chamber 301 by imaging the optical signal 332 output by the encoder head 310 on the surface of the fiber end. Using a metal coated optical fiber to deliver the output beam 332 from the PBS 362 of the optical assembly 310, the means for delivering the output beam 332 contribute no outgassing effluent inside the exposure chamber 301.

At detector module 330, polarizer 336 mixes the measurement and reference beam components of the output beam 332 before the output beam 332 is incident on detector 334. This can be achieved, for example, by orienting the transmission axis of polarizer 336 so that it transmits a component of s-polarized light and a component of p-polarized light (e.g., by orienting the transmission axis at 45° with respect to the plane of the page). In the example illustrated in FIG. 3B, the polarizer 336 that mixes the measurement and reference beam components of the output beam 332 is placed at the input of the detector module 330, outside the exposure chamber 301. In this example, the metal coated optical fiber delivers, from the encoder head 310 to the detector module 330, the unmixed measurement and reference beam components of the output beam 332. As another example, the polarizer 336 that mixes the measurement and reference beam components of the output beam 332 can be part of the encoder head 310 inside the exposure chamber 301. In this other example, the metal coated optical fiber delivers, from the encoder head 310 to the detector module 330, the mixed measurement and reference beam components of the output beam 332.

Encoder system 300′ is an example of an encoder system that has a single detection channel, where the measurement beam 312 makes a single pass to the encoder scale 305. Here, the phase measured at detector 334 will vary depending on motion of encoder scale 305 in the X-direction and the Z-direction. Variations of the encoder system 300′ are possible. For example, the encoder system 300′ includes additional subsystems. For example, in some embodiments, encoder system 300′ includes a local reference which monitors a phase of input beam 322. As depicted in FIG. 3B, a local reference can be provided using a beam splitter 364 (e.g., a NPBS), polarizer 366, and a detector 368. Such a reference can be useful, for example, in embodiments where the relative starting phase between the components of input beam 322 is variable.

In some embodiments, encoder systems can provide more than one measurement channel. Additional channels can be provided by using multiple encoder heads. Alternatively, or additionally, in certain embodiments, a single encoder head can be configured to provide multiple measurement channels.

Additional embodiments of suitable optical encoder designs are disclosed in U.S. Patent Publication No. 2011/0255096 A1 by Leslie L. Deck et al. and entitled “INTERFEROMETRIC ENCODER SYSTEMS,” the contents of which are incorporated herein by reference.

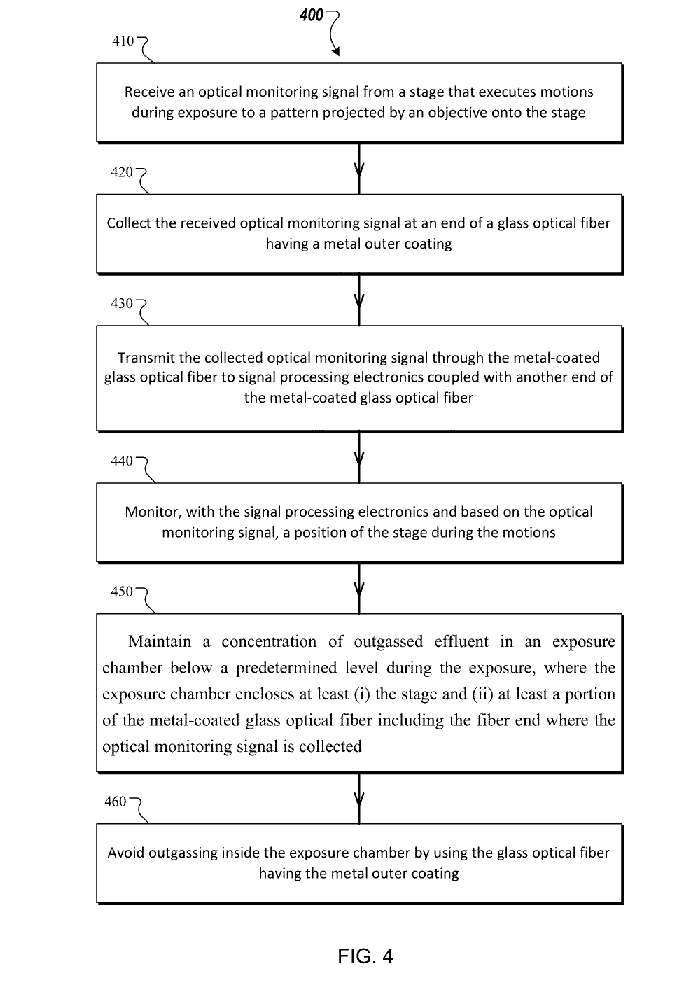

FIG. 4 shows a flow chart that describes a process 400 for maintaining a concentration of outgassed effluent inside an exposure chamber of a lithography system below at predetermined level by using optical sensing technology including an optical signal transport system that does not contribute outgassed effluent in the exposure chamber. The process 400 can be implemented in conjunction with any one of the metrology systems described above with respect to FIGS. 1, 2, 3A and 3B.

At 410, an optical monitoring signal is received from a stage that executes motions during exposure to a pattern projected by an objective onto the stage. In some implementations, the optical monitoring signal can be generated by an optical sensor. For example, the optical sensor can be an encoder. In some cases, the encoder can be operated at a non-Littrow angle.

At 420, the received optical monitoring signal is collected at an end of a metal coated glass optical fiber. In some implementations, the optical monitoring signal can be collected at the fiber end by imaging the optical monitoring signal on the surface of the fiber end. Further, the glass optical fiber can include a core of silica and a cladding of doped silica. Furthermore, the metal outer coating of the glass optical fiber can include one of Al, Cu or Sn. In addition, the metal outer coating of the glass optical fiber can have a thickness in the range of 15 to 50 microns. Also, the metal outer coating of the glass optical fiber can include one of Au, In, Pb, Zn or Ni.

At 430, the collected optical monitoring signal is transmitted through the metal-coated glass optical fiber to signal processing electronics coupled with another end of the metal-coated glass optical fiber. In some implementations, a polarizer can be placed between the stage and the end of the metal-coated glass optical fiber that collects the optical monitoring signal. As such, the polarizer can mix two orthogonally polarized optical signals into an interference signal representing the optical monitoring signal prior to transmission of the interference signal through the metal-coated glass optical fiber. In other implementations, a polarizer can be placed between the other end of the metal-coated glass optical fiber and the signal processing electronics. As such, the polarizer can mix two orthogonally polarized optical signals into an interference signal representing the optical monitoring signal after transmission of the two orthogonally polarized optical signals through the metal-coated glass optical fiber.

At 440, the signal processing electronics monitor, based on the optical monitoring signal, a position of the stage during the motions. In some implementations, the stage position, which is monitored by the signal processing electronics based on the optical monitoring signal, is along a first degree of freedom of the stage.

At 450, a concentration of outgassed effluent in an exposure chamber is maintained below a predetermined level during the exposure, where the exposure chamber encloses at least (i) the stage and (ii) at least a portion of the metal-coated glass optical fiber including the fiber end where the optical monitoring signal is collected.

At 460, outgassing inside the exposure chamber is avoided by using the glass optical fiber having the metal outer coating. In some implementations, one or more other metal-coated glass optical fibers can be used to monitor corresponding one or more other stage positions along respective one or more other degrees of freedom associated with the stage, where the one or more other metal-coated glass optical fibers outgas no effluent inside the exposure chamber.

In general, any of the analysis methods described above, including determining information about a degree of freedom of the sensor scales, can be implemented in computer hardware or software, or a combination of both. For example, in some embodiments, electronic processor 350 can be installed in a computer and connected to one or more encoder systems and configured to perform analysis of signals from the encoder systems. Analysis can be implemented in computer programs using standard programming techniques following the methods described herein. Program code is applied to input data (e.g., interferometric phase information) to perform the functions described herein and generate output information (e.g., degree of freedom information). The output information is applied to one or more output devices such as a display monitor. Each program may be implemented in a high level procedural or object oriented programming language to communicate with a computer system. However, the programs can be implemented in assembly or machine language, if desired. In any case, the language can be a compiled or interpreted language. Moreover, the program can run on dedicated integrated circuits preprogrammed for that purpose.

Each such computer program is preferably stored on a storage medium or device (e.g., ROM or magnetic diskette) readable by a general or special purpose programmable computer, for configuring and operating the computer when the storage media or device is read by the computer to perform the procedures described herein. The computer program can also reside in cache or main memory during program execution. The analysis methods can also be implemented as a computer-readable storage medium, configured with a computer program, where the storage medium so configured causes a computer to operate in a specific and predefined manner to perform the functions described herein.

Other embodiments are in the following claims.

What is claimed is:

1. A lithography system for exposing a resist on a wafer to radiation, the system comprising:
an objective for projecting an image of an object positioned at an object plane to an image plane;
a stage to execute motions relative to the objective while supporting the wafer at the image plane;
an optical sensor for producing an optical monitoring signal associated with the motions of the stage; and
a glass optical fiber having a metal outer coating, the metal-coated glass optical fiber being arranged to provide light to, or collect light from, the optical sensor.

2. The system of claim 1, further comprising:
an exposure chamber enclosing at least (i) the stage and (ii) at least a portion of the metal-coated glass optical fiber comprising the fiber end near the optical sensor, the exposure chamber being arranged and configured to maintain a predefined concentration level of outgassed effluent during the exposure,
wherein the glass optical fiber having the metal outer coating outgasses substantially no effluent inside the exposure chamber.

3. The system of claim 1, wherein the metal-coated glass optical fiber collects light from the optical sensor at one end, the collected light carrying the optical monitoring signal, and
wherein the system further comprises signal processing electronics coupled to another end of the metal-coated glass optical fiber such that the optical monitoring signal is received by the signal processing electronics, the signal processing electronics being configured to monitor, based on the optical monitoring signal, a relative position of the stage.

4. The system of claim 3, wherein the stage position, which is monitored by the signal processing electronics based on the optical monitoring signal, is along a first degree of freedom of the stage.

5. The system of claim 3, further comprising:
one or more other metal-coated glass optical fibers to monitor corresponding one or more other stage positions along respective one or more other degrees of freedom associated with the stage,
wherein the one or more other metal-coated glass optical fibers outgas substantially no effluent inside the exposure chamber.

6. The system of claim 3, where the optical monitoring signal is collected at the fiber end by imaging the optical monitoring signal on the surface of the fiber end.

7. The system of claim 3, further comprising:
a polarizer placed between the stage and the end of the metal-coated glass optical fiber that collects the optical monitoring signal, the polarizer arranged to mix two orthogonally polarized optical signals into an interference signal representing the optical monitoring signal.

8. The system of claim 3, further comprising:
a polarizer placed between the other end of the metal-coated glass optical fiber and the signal processing electronics, the polarizer arranged to mix two orthogonally polarized optical signals representing the optical monitoring signal into an interference signal input to the signal processing electronics.

9. The system of claim 1, further comprising an optical source for the optical sensor, and wherein the metal-coated glass optical fiber provides light to the optical sensor from the optical source.

10. The system of claim 9, wherein the optical source is a heterodyne light source that provides light at two different frequencies with orthogonal polarizations.

11. The system of claim 9, wherein the metal-coated glass optical fiber is a polarization-preserving optical fiber.

12. The system of claim 9, further comprising a second metal-coated glass optical fiber for providing light to the optical sensor from the optical source.

13. The system of claim 1, wherein the optical sensor comprises an interferometric optical encoder system.

14. The system of claim 1, wherein the metal outer coating of the glass optical fiber comprises any of Al, Cu, Sn, Au, In, Pb, Zn, and Ni.

15. The system of claim 14, wherein the metal outer coating of the glass optical fiber has a thickness in the range of 15 to 50 microns.

16. The system of claim 15, wherein the metal outer coating of the glass optical fiber comprises Al, Cu, or Sn.

17. The system of claim 15, wherein the glass optical fiber comprises a core of silica and a cladding of doped silica.

18. The system of claim 1, wherein the metal outer coating of the glass optical fiber has a thickness in the range of 15 to 50 microns.

19. The system of claim 1, wherein the glass optical fiber comprises a core of silica and a cladding of doped silica.

20. The system of claim 1, comprising multiple metal-coated glass optical fibers to provide light to, and collect light from, the optical sensor.
